(19) United States
(12) Patent Application Publication
(10) Pub. No.: US 2012/0025337 A1
(43) Pub. Date: Feb. 2, 2012

(54) MEMS TRANSDUCER DEVICE HAVING STRESS MITIGATION STRUCTURE AND METHOD OF FABRICATING THE SAME

(75) Inventors: Timothy LECLAIR, Longmont, CO (US); David MARTIN, Fort Collins, CO (US)

(73) Assignee: Avago Technologies Wireless IP (Singapore) Pte. Ltd, Singapore (SG)

(21) Appl. No.: 12/844,857

(22) Filed: Jul. 28, 2010

(51) Int. Cl. H01L 29/84; H01L 21/30

(52) U.S. Cl. 257/419; 438/53; 257/E29.324; 257/E21.211

(57) ABSTRACT

A micro-electromechanical systems (MEMS) transducer device mounted to a package substrate includes an active transducer having a resonator stack formed over a cavity through a transducer substrate, and a stress mitigation structure between the transducer substrate and the package substrate. The stress mitigation structure reduces stress induced on the transducer substrate due to mismatched coefficients of thermal expansion (CTEs) of the transducer substrate and the package substrate, respectively.

### BACKGROUND

Transducers generally convert electrical signals to mechanical signals or vibrations, and/or mechanical signals or vibrations to electrical signals. Acoustic transducers, in particular, convert electrical signals to acoustic signals (sound waves) in a transmit mode (e.g., a speaker application), and/or convert received acoustic waves to electrical signals in a receive mode (e.g., a microphone application). Transducers, such as ultrasonic transducers, are provided in a wide variety of electronic applications, including filters. As the need to reduce the size of many components continues, the demand for reduced-size transducers continues to increase, as well. This has led to comparatively small transducers, which may be micromachined according to various technologies, such as micro-electromechanical systems (MEMS) technology.

Various types of MEMS transducers, such as piezoelectric ultrasonic transducers (PMUTs), include a resonator stack, having a layer of piezoelectric material between two conductive plates (electrodes), formed on a thin membrane. The membrane may be formed on a substrate over a cavity passing through the substrate. Typically, the substrate is formed of a material compatible with semiconductor processes, such as silicon (Si). The transducers may packaged by polishing the back side of the transducer substrate and mounting the polished transducer substrate directly onto a package substrate. For example, when the transducer is to be included in a lead frame package, the transducer substrate is typically mounted on a metal package substrate.

In conventional packaging, a coefficient of thermal expansion (CTE) of the transducer is significantly different from the CTE of the package in which it is mounted. Generally, CTE indicates the rate or proportion of change of a material or structure with respect to changes in temperature. The difference between the transducer and package CTEs results in varying responses to changes in temperature, both during packaging processes and during operation, which impose physical stress on the transducer. In other words, the source of parametric shifts in MEMS bending mode and/or thickness mode transducers due to die mounting and operating temperature variation, for example, is mismatch of thermal properties between the materials of the transducer and the package. The stress is most pronounced between the transducer substrate and the package substrate to which the transducer substrate is attached, due to the physical contact and significant CTE mismatch of the respective materials.

### SUMMARY

In a representative embodiment, a micro-electromechanical systems (MEMS) transducer device mounted to a package substrate includes an active transducer formed on a transducer substrate, and a stress mitigation structure between the transducer substrate and the package substrate. The stress mitigation structure reduces stress induced on the transducer substrate due to mismatched coefficients of thermal expansion (CTEs) of the transducer substrate and the package substrate, respectively.

In another representative embodiment, a method is provided for forming a packaged MEMS transducer device. The method includes forming a membrane on a top surface of a transducer substrate, the transducer substrate having a first CTE; forming a resonator stack on the membrane; forming a stress mitigation structure on a bottom surface of the transducer substrate; etching the stress mitigation structure and the transducer substrate to form a substrate cavity under the membrane; and attaching the stress mitigation structure to a package substrate having a second CTE different from the first CTE. The stress mitigation structure reduces stress induced on the transducer substrate due to the difference between the first and second CTEs.

In another representative embodiment, a packaged MEMS transducer device includes a transducer substrate having a first CTE, a membrane on the transducer substrate over a cavity formed through the transducer substrate, a resonator stack on the membrane, and a stress mitigation structure between the transducer substrate and a package substrate having a second CTE greater than the first CTE. The stress mitigation structure has a third CTE less than both the first CTE and the second CTE, the stress mitigation structure counter-acting physical responses of the package substrate to temperature fluctuations to reduce stress induced onto the transducer substrate.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a cross-sectional diagram illustrating a packaged transducer device, according to a representative embodiment.

FIGS. 2A-2G are cross-sectional diagrams illustrating steps in a fabrication process of transducer devices, according to a representative embodiment.

FIG. 3 is a plan view illustrating a stress mitigation structure configured to act as an etch mask, according to a representative embodiment.

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the representative embodiments. Such methods and apparatuses are clearly within the scope of the present teachings.

Generally, it is understood that the drawings and the various elements depicted therein are not drawn to scale. Further, relative terms, such as “above,” “below,” “top,” “bottom,” “upper,” “lower,” “left,” “right,” “vertical” and “horizontal,” are used to describe the various elements' relationships to one another, as illustrated in the accompanying drawings. It is understood that these relative terms are intended to encompass different orientations of the device and/or elements in addition to the orientation depicted in the drawings. For example, if the device were inverted with respect to the view in the drawings, an element described as “above” another element, for example, would now be “below” that element. Likewise, if the device were rotated 90 degrees with respect to the view in the drawings, an element described as “vertical,” for example, would now be “horizontal.”

According to various embodiments, a transducer device, such as a MEMS ultrasonic transducer or a PMUT, includes an active transducer on a top surface of a transducer substrate and a stress mitigation structure on a bottom (opposite) surface of the transducer substrate. The active transducer includes a resonator stack, having a layer of piezoelectric material between two conductive plates (electrodes), formed on a membrane. The transducer device is mounted in a package, for example, by attaching the transducer device to a package substrate through the stress mitigation structure. The stress mitigation structure reduces or eliminates the effects of a CTE mismatch between the package substrate and the transducer substrate.

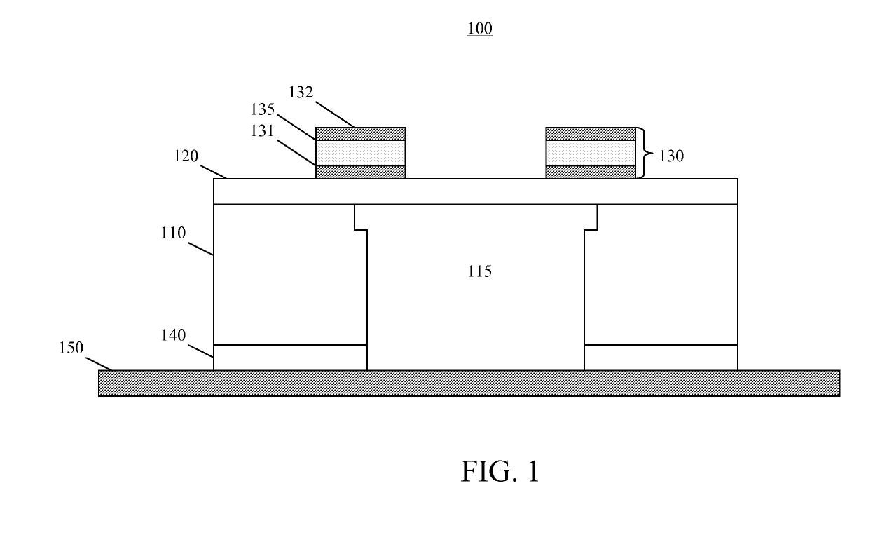

FIG. 1 is a cross-sectional diagram illustrating a packaged transducer device 100, according to a representative embodiment. The transducer device 100 is depicted as a singulated die, e.g., after separation from a wafer, mounted in a package, indicated by representative package substrate 150. The package substrate may be formed from any material compatible with semiconductor and/or MEMS transducer packaging processes, such as copper (Cu), zinc (Zn), Cu/Zn alloys, aluminum (Al), or the like.

Referring to FIG. 1, the transducer device 100 may be an ultrasonic MEMS transducer, for example, although it is understood that other types of transducers may be incorporated without departing from the scope of the present teachings. The transducer device 100 includes transducer substrate 110, membrane 120 and resonator or resonator stack 130, where the membrane 120 and the resonator stack 130 form an active transducer, e.g., over cavity 115 formed through a backside of the transducer substrate 110. In the depicted embodiment, the membrane 120 is formed of a single layer of membrane material, although the membrane 120 may have multiple layers without departing from the scope of the present teachings. The resonator stack 130 includes first electrode 131 disposed over a portion of the membrane 120, and piezoelectric layer 135 and second electrode 132 stacked on the first electrode 131.

In the depicted embodiment, the resonator stack 130 is shown as an annular resonator, where the cross-section is taken across the center. The annular resonator stack 130 may be substantially circular in shape, for example, although it may be formed in different shapes, such as ovals, squares, rectangles, or the like, without departing from the scope of the present teachings. Further, in various embodiments, the resonator stack 130 need not have annular shape, but may simply be a solid resonator stack on the substrate 110. The resonator stack 130 is substantially centered over the cavity 115, enabling mechanical movement of the membrane 120 and/or the resonator stack 130. Application of a time-dependent voltage to the resonator stack 130 causes a mechanical wave to be launched through the resonator stack 130 and the membrane 120. Generally, as the piezoelectric layer 135 of the resonator stack 130 and/or the membrane 120 oscillate in response to a mechanical perturbation (e.g., sound waves), forces generated by the perturbation induce stresses in the piezoelectric layer 135 resulting in generation of a voltage difference across the first and second electrodes 131, 132.

The transducer substrate 110 may be formed of various types of materials compatible with semiconductor processes, such as silicon (Si), gallium arsenide (GaAs), indium phosphide (InP), glass, sapphire, alumina, or the like, which is useful for integrating connections and electronics, thus reducing size and cost. The cavity 115 formed through the transducer substrate 110 may be substantially the same shape as the resonator stack 130, e.g., circular, although it may have any of a variety of sizes and shapes, such as oval, square, rectangular, or the like, without departing from the scope of the present teachings. The cavity 115 may be obtained by back side etching the bottom surface of the transducer substrate 110, which may include a dry etch process, such as a Bosch process, for example, although various alternative techniques may be incorporated. Formation of the transducer substrate 110 and the resonator stack 130 (on a membrane) is described, for example, by MARTIN et al. in U.S. patent application Ser. No. 12/495,443, which is hereby incorporated by reference.

In various embodiments, the transducer substrate 110 is formed of a different material than the package substrate 150. Accordingly, the transducer substrate 110 has a first CTE corresponding to the material from which it is formed, and the package substrate 150 has a second CTE corresponding to the material from which it is formed, where the first and second CTE are different from one another, resulting in a CTE mismatch. Typically, the second CTE is greater than the first CTE, indicating that the package substrate 150 expands at a greater rate in response to increases in temperature than the rate at which the transducer substrate 110 expands. Likewise, the greater second CTE results in the package substrate 150 contracting at a greater rate in response to decreases in temperature than the rate at which the transducer substrate 110 contracts. For example, when the transducer substrate 110 is formed of Si, the first CTE is about 2.5, and when the package substrate 150 is formed of Cu, the second CTE is about 17. Of course, the second CTE may be less than the first CTE in various configurations, although the same stress mitigation techniques described herein apply.

As discussed above, the difference (mismatch) between the first and second CTEs causes stress to be transferred to the transducer device 100, and more particularly to the transducer substrate 110, in response to temperature fluctuations, e.g., during die attach and other assembly processes and/or during operation the transducer device 100 after being mounted to the package substrate 150. The temperature fluctuations may result from changes in various conditions, including ambient environmental temperature, internally generated heat, or the like. Thus, according to various embodiments, the stress mitigation structure 140 is added to the bottom surface of the transducer substrate 110 prior to attaching the transducer device 100 to the package substrate 150. The stress mitigation structure 140 reduces the stress, e.g., induced on the transducer substrate 110 and/or other components of the transducer device 100, otherwise caused by the mismatch between the first and second CTEs. The various types and functionalities of the stress mitigation structure 140 are discussed below. Although FIG. 1 depicts a singulated die, it is understood that the stress mitigation structure 140 may be added to the bottom surface of the transducer substrate 110 prior to separating the transducer device 100, at which point the transducer substrate 110 is part a wafer substrate on which multiple active transducers are formed, as discussed below.

The membrane 120 may be formed of includes various materials compatible with semiconductor processes, such as boron silicate glass (BSG), silicon dioxide (SiO₂), silicon nitride (SiN), polysilicon, aluminum nitride (AlN), or the like. The first and second electrodes 131, 132 may be formed of an electrically conductive material, such as molybdenum (Mo), tungsten (W), aluminum (Al), or the like. The first and second electrodes 131, 132 are electrically connected to external circuitry via contact pads (not shown), which may be formed of a conductive material, such as gold, gold-tin alloy or the like. The piezoelectric layer 135 may be formed of a thin film of piezoelectric material, such as AlN, zinc oxide (ZnO), lead zirconium titanate (PZT), or other piezoelectric film compatible with semiconductor processes. The thickness of the membrane 120 may range from about 0.05 μm to about 20 μm, thicknesses of the first and second electrodes 131, 132 may range from about 0.05 μm to about 10 μm, and the thickness of the piezoelectric layer 135 may range from about 0.1 μm to about 10 μm, for example, although the respective thicknesses may vary to provide unique benefits for any particular situation or to meet application specific design requirements of various implementations, as would be apparent to one skilled in the art.

In various embodiments, one or more passivation layers (not shown) may be formed on top and side surfaces of the resonator stack 130 and exposed portions of the membrane 120. The passivation layer(s) may be formed of various types of materials compatible with semiconductor processes, including BSG, SiO₂, SiN, polysilicon, AlN, or the like, and may include multiple layers of the same or different materials. The total thickness of the passivation layer is generally sufficient to insulate the layers of the transducer device 100 from the environment, including protection from moisture, corrosives, contaminants, debris or the like, to which the transducer device 100 would otherwise be exposed. Passivation may have other design requirements to achieve desired frequency and sensitivity, as would be apparent to one of ordinary skill in the art.

Referring again to FIG. 1, the stress mitigation structure 140 may be formed from a variety of materials, without departing from the scope of the present teachings. Depending on the type of material used, the stress mitigation structure 140 reduces the effects of CTE mismatch between the first and second CTEs of the transducer substrate 110 and the package substrate 150, respectively, by different means. For example, the stress mitigation structure 140 may be formed of a material having a third CTE that effectively negates the mismatch between the first and second CTEs (which may be referred to herein as “CTE negating material”). Alternatively, the stress mitigation structure 140 may be formed of a material that, regardless of its CTE, physically isolates the transducer substrate 110 from the package substrate 150 (which may be referred to herein as “isolating material”). The stress mitigation structure 140 may also be formed of one or more materials that combine properties of both a CTE negating material and an isolating material.

More particularly, according to various embodiments, the stress mitigation structure 140 may be is formed of a CTE negating material having a third CTE lower than the first and second CTEs when the second CTE of the package substrate 150 is higher than the first CTE, and having a third CTE higher than the first and second CTEs when the second CTE is lower than the first CTE. The stress mitigation structure 140 thus reduces stress on the transducer device 100 by effectively counter-acting or “netting out” the physical responses of the package substrate 150 to temperature fluctuations before they induce stress onto the transducer substrate 110, thus negating the mismatch between the first and second CTEs, in whole or in part.

According to various alternative embodiments, when the stress mitigation structure 140 is formed of an isolating material that physically isolates the transducer substrate 110 from the package substrate 150, the stress mitigation structure 140 reduces stress on the transducer device 100 by blocking or otherwise absorbing the physical responses of the package substrate 150 to temperature fluctuations. Of course, as mentioned above, further embodiments may include a stress mitigation structure 140 formed of one or more materials that combine aspects of both CTE negating materials and isolating materials, described above, in various proportions.

Illustrative embodiments of the transducer device 100 with different materials as the stress mitigation structure 140 are discussed below. For purposes of simplifying the description, it is assumed that the transducer substrate 110 is formed of Si and the package substrate 150 is formed of Cu, for example, although the concepts apply with various alternative materials, taking into account the respective relative prosperities of these materials, as would be apparent to one of ordinary skill in the art.

According to an embodiment, the stress mitigation structure 140 is an oxide film, such as SiO₂, grown or otherwise deposited on the bottom surface of the transducer substrate 110. SiO₂, in particular, has a much lower CTE than Si, as well as a lower CTE than Cu, for example. Thus, the third CTE of the stress mitigation structure 140 formed of SiO₂ is less than both the first CTE of the transducer substrate 110 formed of Si and the second CTE of the package substrate 150 formed of Cu. Accordingly, the stress mitigation structure 140 counteracts the stress induced on the transducer substrate 110 by the package substrate 150 in response to temperature fluctuations. The stress mitigation structure 140 may be a relatively thick oxide film, e.g., about 1 μm to about 20 μm, which may be applied using a chemical vapor deposition (CVD) process, for example. Otherwise, the oxide film may be applied using thermal oxidation.

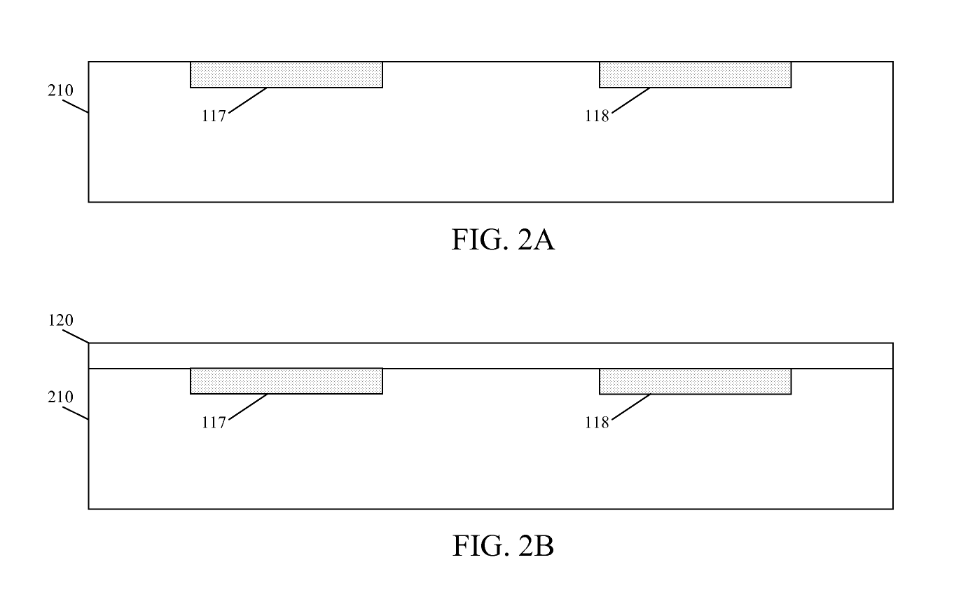

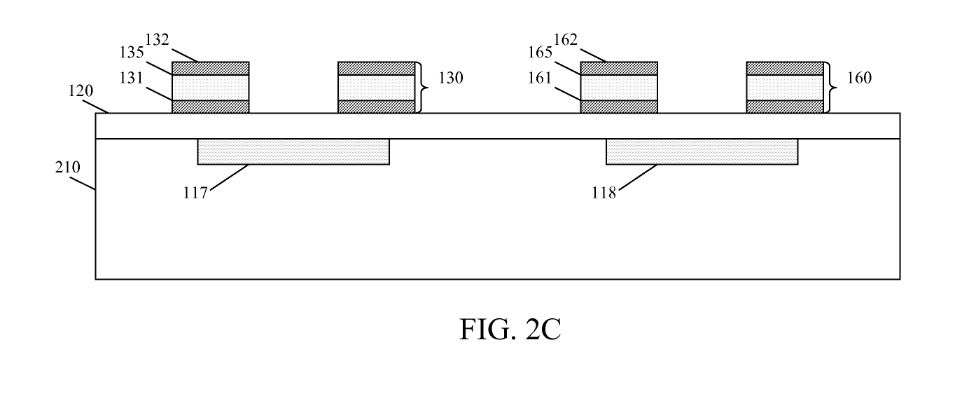

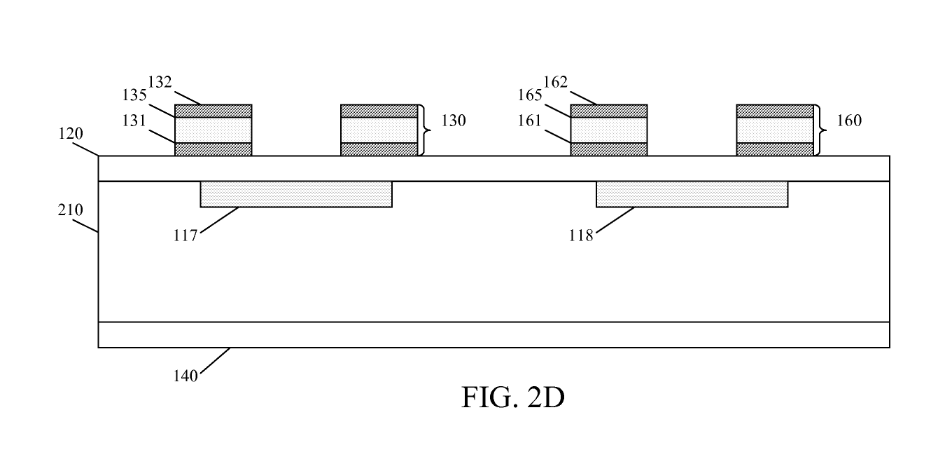

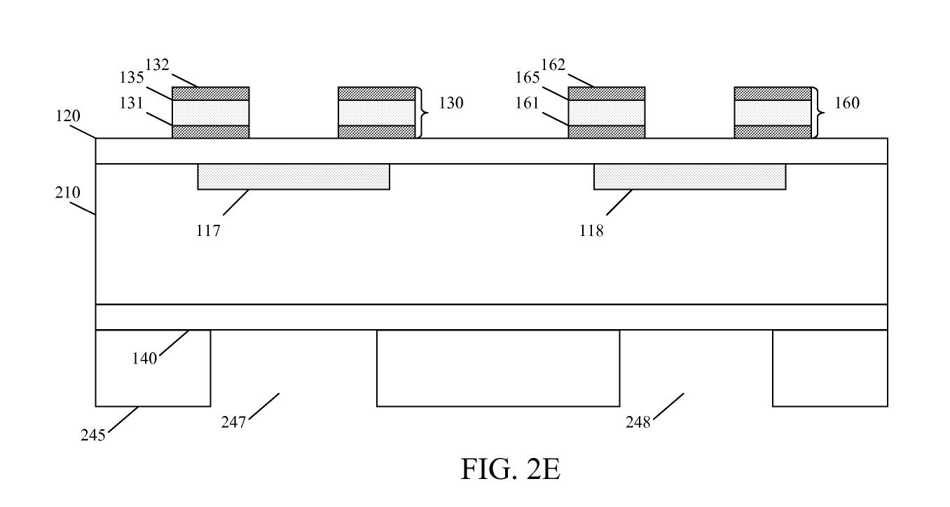

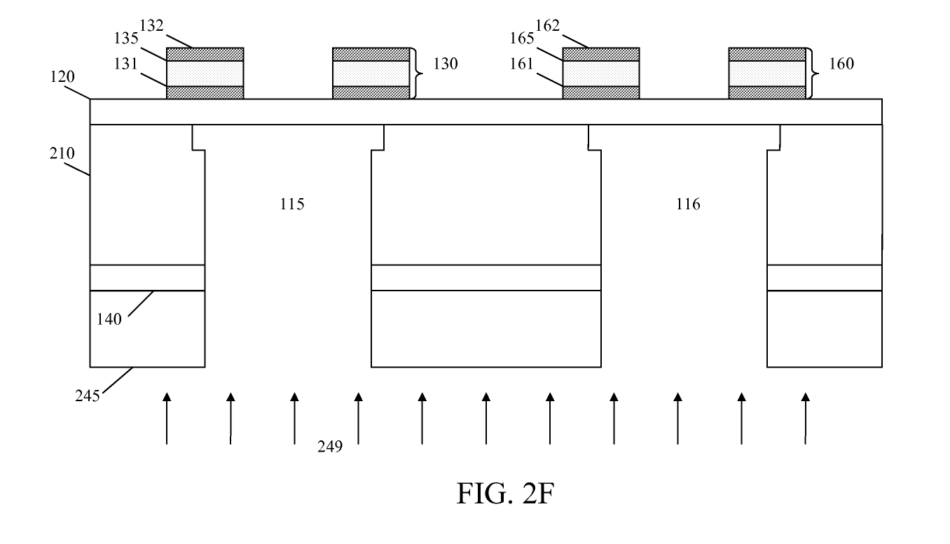

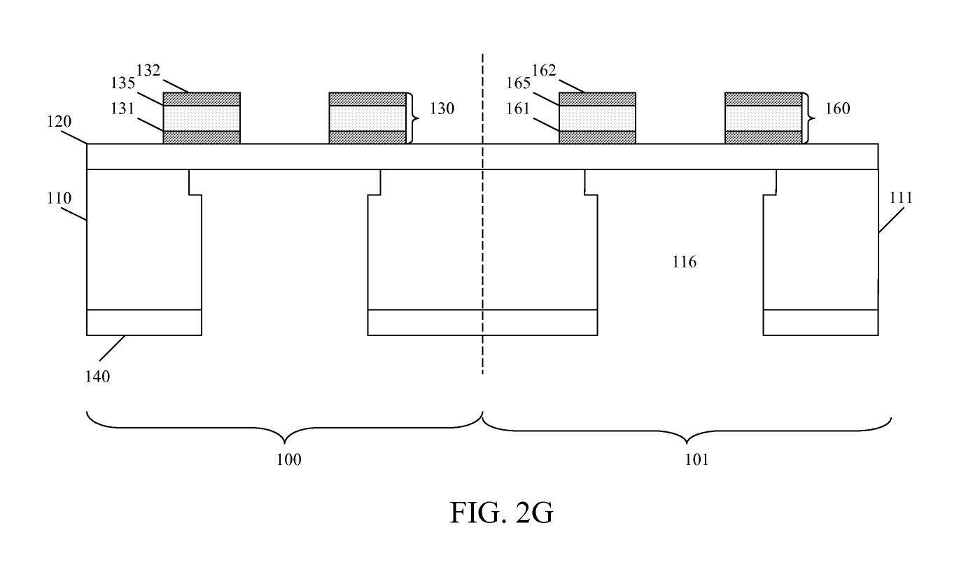

According to another embodiment, the stress mitigation structure 140 may be a thin film of a non-etchable oxide, such as BSG, for example. That is, the chemical composition of the oxide is modified to make it non-etchable in release-etch chemistry. For example, MEMS transducer devices may utilize a sacrificial material, such as photoresist pattern or etch mask 245 discussed below with reference to FIGS. 2E-2G, which is etched at the end of the fabrication process. A stress mitigation structure 140 formed of non-etchable oxide would survive this etch. For example, if hydrofluoric acid (HF) is used as the release-etch chemistry, a boron-doped oxide, such as BSG, would be resistant to the etch. The stress mitigation structure 140 formed of a non-etchable oxide may be deposited on the Si of the transducer substrate 110 using various deposition techniques, such as a CVD process, for example.

According to another embodiment, the stress mitigation structure 140 may be a thin film of a chemically optimized dielectric material, including chemically optimized dielectric glass. Chemically optimized refers to a dielectric material having a composition designed to meet compatibility with the wafer manufacturing process and that provides the desired CTE. Examples of a chemically optimized dielectric include various materials other than SiO₂, such as SiN and AlN. The stress mitigation structure 140 formed of chemically optimized dielectric material may be deposited on the Si of the transducer substrate 110 using various deposition techniques, such as a CVD process, for example.

According to another embodiment, the stress mitigation structure 140 is a sheet of material or a separate wafer bonded to the bottom of the transducer substrate 110 using any of various lamination techniques. For example, the stress mitigation structure 140 may be formed of alumina, sapphire, doped Si0₂ (e.g., BSG or Pyrex®), or the like, bonded to the transducer substrate 110. In contrast to the three previously described embodiments which involve thin films, the lamination technique allows a much thicker interposer material between the transducer substrate 110 and the package substrate 150, resulting in greater mitigation of package induced stresses. Therefore, when the material of the stress mitigation structure 140 has a third CTE less than both the first CTE of the Si transducer substrate 110 and the second CTE of the Cu package substrate 150, as well as a substantial thickness, the lamination technique provides mitigation of package induced stresses both by negating the CTE mismatch between the transducer substrate 110 and the package substrate 150, and by physically isolating the transducer substrate 110 from the package substrate 150.

According to yet another embodiment, the stress mitigation structure 140 may be an organic compliant coating, such as benzocyclobutene (BCB) or SU-8 or other photoresist film, for example. The organic compliant film is an isolating material (as opposed to a CTE negating material), and thus the organic compliant film blocks, absorbs, or otherwise reduces the magnitude of the stress transferred into the transducer substrate 110. For example, the stress mitigation structure 140 may be formed of BCB having a thickness of about 0.5 μm to about 50 μm. This approach may be somewhat less robust than negating the mismatch between the first and second CTEs, discussed above, although it may suitable to applications with benign operating environments.

As stated above, the transducer device 100 may be an ultrasonic transducer fabricated using MEMS technology. When the transducer device 100 is a PMUT, for example, the translation is made through a piezoelectric material, e.g., by the piezoelectric layer 135. In various alternative embodiments, the transducer device 100 may be any type of micromachined transducer with a membrane having stress as a significant parameter, such as a capacitive micro-machined ultrasonic transducer (CMUT), in which case the translation is made through a capacitance variation. It is understood that other types and arrangements of transducers may be incorporated, without departing from the scope of the present teachings.

FIGS. 2A-2G are cross-sectional diagrams illustrating steps in a fabrication process of multiple transducer devices on a wafer substrate, according to a representative embodiment. Although FIGS. 2A-2G show formation of only two transducer devices on the wafer substrate, it is understood that the embodiments are not limited by this example and that the number of transducer devices may vary to provide unique benefits for any particular situation or to meet application specific design requirements of various implementations or fabrication techniques, as would be apparent to one skilled in the art.

Referring to FIG. 2A, “swimming pools” or recesses 117, 118 are formed in a top surface of wafer substrate 210, by machining or by chemically etching the wafer substrate 210 using photolithography, although various alternative techniques may be incorporated. The wafer substrate 210 may be formed of Si, GaAs, InP, glass, sapphire or alumina, for example, although any of a variety of materials compatible with semiconductor processes may be incorporated. In an embodiment, each of the recesses 117, 118 may be about 2 μm to about 3 μm deep, for example. The recess is filled with a sacrificial material, such as a phosphosilicate glass (PSG) film, for example. A chemical mechanical polish (CMP) may be performed to create a planar top surface.

Referring to FIG. 2B, membrane 120 is formed on the top surfaces of the substrate 210 and PSG filled recesses 117, 118, for example, using CVD, spin-on, sputtering, or evaporation techniques. The membrane 120 may be formed of various materials compatible with semiconductor processes, such as BSG, SiO₂, SiN, polysilicon, AlN, or the like. Resonator stacks 130, 160 are then formed on the top surface of the membrane 120 over the recesses 117, 118, respectively, as shown in FIG. 2C.

The resonator stack 130 may be an annular resonator including piezoelectric layer 135 formed between first and second electrodes 131, 132, and the resonator stack 160 may be an annular resonator including piezoelectric layer 165 formed between first and second electrodes 161, 162. The resonator stacks 130, 160 and may be formed by sequentially applying a layer of an electrically conductive material, such as Mo, W, Al, or the like, for first electrodes 131, 161, a piezoelectric thin film, such as AlN, ZnO, or PZT for piezoelectric layers 135, 165, and another layer of the electrically conductive material for second electrodes 132, 162. One or more passivation layers (not shown) may be included as well. The conductive layers may be respectively patterned, for example, using photolithography, although various alternative techniques may be incorporated, to provide the desired shapes of the first electrodes 131, 161 and second electrodes 161, 162.

Referring to FIG. 2D, stress mitigation layer 140 is applied to the (polished) bottom surface of the native wafer substrate 210. As discussed above, the stress mitigation layer 140 may be formed of a variety of materials for mitigating stress on the wafer substrate 210 induced by a package substrate to which the transducer devices are mounted following separation of the wafer substrate into singulated dies, discussed below with reference to FIG. 2G. The material of the stress mitigation layer 140 may be CTE negating material or an insulating material or a combination of both, and the technique for applying the stress mitigation layer 140 depends, in part, on the type of material, as would be apparent to one of ordinary skill in the art.

For convenience of illustration, FIG. 2D depicts the wafer substrate 210, the membrane 120 and the resonator stacks 130, 160 in the same orientation as during the assembly steps shown in FIGS. 2A-2C. It is understood, however, that the actual orientation may differ depending on the technique for applying the stress mitigation layer 140. For example, the assembled wafer substrate 210, the membrane 120 and the resonator stacks 130, 160 may be inverted to enable CVD, spin-on, sputtering, or evaporation techniques, for example, as would be apparent to one of ordinary skill in the art.

When the stress mitigation layer 140 is formed of SiO₂ or other oxide film, for example, the SiO₂ material may be grown on the bottom surface of the wafer substrate 210 using thermal oxidation. Alternatively, the SiO₂ material may deposited using CVD, sputtering or thermal growth techniques, for example, which enables deposition of a thicker (e.g., about 1 μm to about 20 μm) layer of the SiO₂ material. When the stress mitigation layer 140 is formed of some other type of thin film, such as non-etchable oxide (e.g., BSG) or chemically optimized dielectric (e.g., SiN or AlN), as discussed above, the material may deposited using CVD or sputtering techniques, for example.

When stress mitigation structure 140 is formed of an organic compliant coating (e.g., BCB or SU-8) or other isolating material, as discussed above, the stress mitigation structure 140 is relatively thicker. For example, when the stress mitigation structure 140 is formed of BCB, it is deposited to a thickness of about 0.5 μm to about 50 μm. The isolating material may be deposited using spin-on or sputtering techniques, for example.

Also, as discussed above, the stress mitigation structure 140 may be a sheet of material or separate wafer that is laminated or otherwise bonded to the bottom of the transducer substrate 110 using various lamination or bonding techniques. In this case, the stress mitigation structure 140 may be formed of alumina, sapphire, doped SiO₂ (e.g., BSG or Pyrex®), or the like, for example. The sheet of material or separate wafer may include a CTE negating material having a third CTE that substantially or partially negates the difference between the first CTE of the wafer substrate 210 and a second CTE of the package substrate (not shown in FIG. 2D), and/or an isolating material that physically blocks or otherwise absorbs the physical responses of the package substrate to temperature fluctuations. The thickness of the laminated stress mitigation structure 140 varies depending on the materials used for the package substrate, the wafer substrate 210 and the stress mitigation structure 140. For example, when the package substrate is Cu, the wafer substrate 210 is Si and stress mitigation structure 140 is alumina, the stress mitigation structure 140 to be laminated may have a thickness of about 50 μm to about 1000 μm.

Referring to FIGS. 2E and 2F, photoresist pattern or etch mask 245 is deposited on the stress mitigation structure 140. The etch mask 245 includes a pattern of holes 247, 248 that substantially align with the recesses 117, 118. Then, etching process 249 is performed to form cavities 115, 116 through the holes 247, 248, respectively. In addition, the etching process removes the sacrificial material (e.g., PSG) from the recesses 117, 118, to expose corresponding portions of the bottom surface of the membrane 120. The etching process may include any dry or liquid etching process compatible with semiconductor fabrication processes for the respective materials. For example, reactive ion etching (RIE) may be used for etching BSG, either RIE or HF based wet etching may be used for SiO₂, and RIE or phosphoric acid based wet etching may be used for SiN, although other types of etching may be incorporated without departing from the scope of the present teachings.

As discussed above, for convenience of illustration, FIGS. 2E and 2F depict the wafer substrate 210, the membrane 120 and the resonator stacks 130, 160 in the same orientation as during the assembly steps shown in FIGS. 2A-2C, and thus the etching process 249 is shown by arrows pointing in an upward direction. It is understood, however, that the assembled wafer substrate 210, the membrane 120 and the resonator stacks 130, 160 may actually be inverted during the etching process 249, for example, as would be apparent to one of ordinary skill in the art.

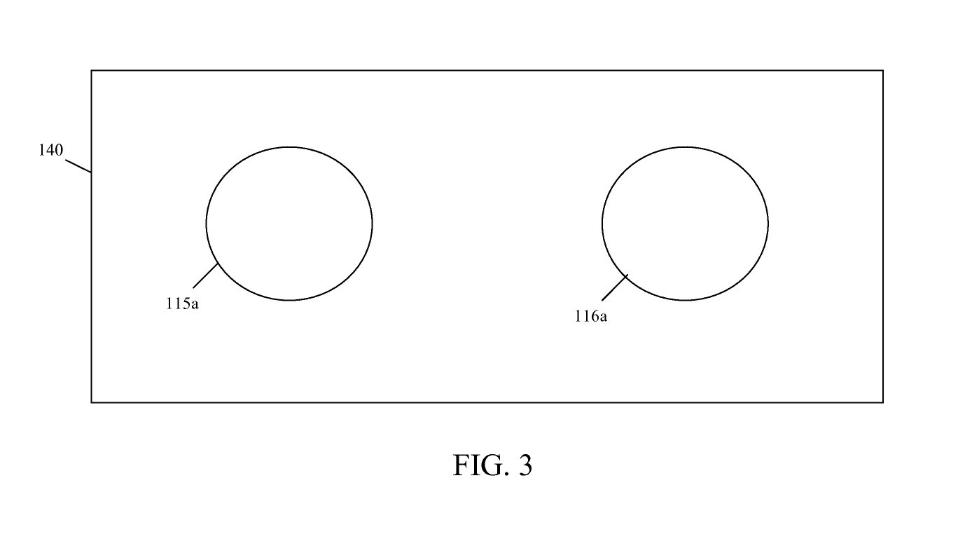

The etch mask 245 may be formed by machining or by chemically etching a mask layer (not shown), previously applied to the stress mitigation structure 140, using photolithography, although various alternative techniques may be incorporated. However, in various embodiments where the stress mitigation structure 140 is a sheet of material or a separate wafer to be laminated to the wafer substrate 210, the stress mitigation structure 140 may itself be used as the etch mask in place of the etch mask 245. For example, FIG. 3 is a plan view illustrating the stress mitigation structure 140 configured to act as an etch mask, according to a representative embodiment. Prior to lamination, holes 115a, 116a are formed in the stress mitigation structure 140, for example, by drilling, machining, chemically etching, or the like. Once the stress mitigation structure 140 is laminated to the wafer substrate 210, the holes 115a, 116a substantially align with the recesses 117, 118. The etching process 249 may then be performed (without the etch mask 245) to form cavities 115, 116.

Referring to FIG. 2G, the etch mask 245 chemically released or etched, using a wet etch process including HF etch solution, although the etch mask 245 may be removed by various other techniques, such as a lift-off process. Of course, in various embodiments where the stress mitigation structure 140 is used as the etch mask, the step of removing the etch mask 245 is not performed.

As discussed above, the transducer devices 100, 101 may be singulated into corresponding dies (indicated by the vertical dashed line in FIG. 2G) prior to being packaged or otherwise mounted on a package substrate, such as the package substrate 150 shown in FIG. 1. The transducer devices 100, 101 may be singulated using any separation process compatible with semiconductor fabrication processes, such as scribe and break, mechanical or laser sawing, or the like. After separation, the transducer device 100 includes stress mitigation structure 140 formed on one surface of transducer substrate 110 and an active transducer, including resonator stack 130 formed on membrane 120 over cavity 115, on the opposite surface of the transducer substrate 110. Likewise, the transducer device 101 includes stress mitigation structure 140 formed on one surface of transducer substrate 111 and an active transducer, including resonator stack 160 formed on membrane 120 over cavity 116, on the opposite surface of the transducer substrate 111.

The transducer devices 100, 101, including the corresponding stress mitigation structures 140, may then be separately packaged, for example, in any of a variety of packaged devices, such as lead frames, dual-in-line packages, outline packages, ceramic packages (e.g., alumina), or the like. The packaging may be single chip packaging, e.g., including only one transducer device 100, 101, or multi-chip packaging, e.g., including both transducer devices 100, 101 or one transducer device 100, 101 with another chip. In various embodiments, the stress mitigation structure 140 is attached to the package substrate using various die attach adhesives, for example. The packaging may include addition of a lid to encapsulate the transducer devices 100, 101. Post processing may then be performed on the packages, including curing, wire bonding, etc.

Generally, examples of methods, materials and structures for fabricating a transducer device (e.g., without stress mitigation structures and associated fabrication techniques and processes) are described by RUBY et al. in U.S. Pat. Nos. 5,587,620, 5,873,153, 6,384,697 and 7,275,292; by BRADLEY et al. in U.S. Pat. No. 6,828,713; by FAZZIO et al. in U.S. Patent Application Pub. Nos. 2008/0122320 and 2008/0122317; by JAMNEALA et al. in U.S. Patent Application Pub. No. 2007/0205850; by RUBY et al. in U.S. Patent Application Pub. No. 2008/0258842; by FENG et al. in U.S. Patent Application Pub. No. 2006/0103492; and by MARTIN et al. in U.S. patent application Ser. No. 12/495,443; all of which are hereby incorporated by reference.

In alternative embodiments, the wafer substrate 210 may be formed with no cavities 117, 118. For example, using solidly mounted resonator (SMR) technology, the first and second resonator stacks 130, 160 may be formed over corresponding acoustic mirrors or Bragg Reflectors (not shown), having alternating layers of high and low acoustic impedance materials, formed in the wafer substrate 210. An acoustic reflector may be fabricated according to various techniques, an example of which is described by LARSON, III, et al. in U.S. Pat. No. 7,358,831, which is hereby incorporated by reference.

Notably, the teachings of the incorporated patents and patent applications are intended to be illustrative of methods, materials and structures useful to the present teachings, but in no way limiting to the present teachings.

According the various embodiments, a stress mitigation structure is able to mitigate differential materials thermal expansion stresses between a transducer device (e.g., a MEMS die) and a supporting package substrate, for example. The differential stresses to which the transducer device is subjected during package mounting processes required to permit the transducer device to be interconnected to end products/systems are reduced or eliminated. Likewise, differential stresses to which the transducer device is subjected during the functioning of such end product/systems in service, as surrounding temperatures shift to their high and low extremes, are reduced or eliminated.

The various components, materials, structures and parameters are included by way of illustration and example only and not in any limiting sense. In view of this disclosure, those skilled in the art can implement the present teachings in determining their own applications and needed components, materials, structures and equipment to implement these applications, while remaining within the scope of the appended claims.

1. A micro-electromechanical systems (MEMS) transducer device mounted to a package substrate, the device comprising:
an active transducer formed on a transducer substrate; and
a stress mitigation structure between the transducer substrate and the package substrate, the stress mitigation structure reducing stress induced on the transducer substrate due to mismatched coefficients of thermal expansion (CTEs) of the transducer substrate and the package substrate, respectively.

2. The device of claim 1, wherein the transducer substrate has a first CTE, and the package substrate has a second CTE greater than the first CTE, and
wherein the stress mitigation structure has a third CTE less than the first and second CTEs to counter-act the stress on the transducer substrate caused by the mismatched first and second CTEs.

3. The device of claim 1, wherein the transducer substrate has a first CTE, and the package substrate has a second CTE greater than the first CTE, and
wherein the stress mitigation structure is formed of an isolating material that blocks physical responses of the package substrate from inducing stress on the transducer substrate caused by the mismatched first and second CTEs.

4. The device of claim 1, wherein the stress mitigation structure comprises a film of silicon dioxide.

5. The device of claim 4, wherein the film of silicon dioxide has a thickness of about 1 μm to about 20 μm.

6. The device of claim 1, wherein the stress mitigation structure comprises a thin film of non-etchable oxide.

7. The device of claim 6, wherein the non-etchable oxide comprises boron silicate glass (BSG).

8. The device of claim 1, wherein the stress mitigation structure comprises a thin film of chemically optimized dielectric material.

9. The device of claim 8, wherein the chemically optimized dielectric material comprises one of silicon nitride or aluminum nitride.

10. The device of claim 1, wherein the stress mitigation structure is laminated to the transducer substrate.

11. The device of claim 10, wherein a material of the stress mitigation structure comprises one of doped Si0₂, alumina or sapphire.

12. The device of claim 1, wherein the stress mitigation structure comprises an organic compliant coating.

13. The device of claim 12, wherein the organic compliant coating comprises one of benzocyclobutene or an SU-8 photoresist film.

14. A method of forming a packaged micro-electromechanical systems (MEMS) transducer device, the method comprising:
forming a membrane on a top surface of a transducer substrate, the transducer substrate having a first coefficient of thermal expansion (CTE);
forming a resonator stack on the membrane;
forming a stress mitigation structure on a bottom surface of the transducer substrate;
etching the stress mitigation structure and the transducer substrate to form a substrate cavity under the membrane; and
attaching the stress mitigation structure to a package substrate having a second CTE different from the first CTE, the stress mitigation structure reducing stress induced on the transducer substrate due to the difference between the first and second CTEs.

15. The method of claim 14, further comprising:
singulating the transducer device from a wafer prior to attaching the stress mitigation structure to the package substrate.

16. The method of claim 14, wherein forming the stress mitigation structure on the bottom surface of the transducer substrate comprises depositing a thin film of one of silicon dioxide, a non-etchable oxide or a chemically optimized dielectric.

17. The method of claim 14, wherein forming the stress mitigation structure on the bottom surface of the transducer substrate comprises:
forming a hole through a stress mitigation material; and
laminating the stress mitigation material to the bottom surface of the transducer substrate, wherein the hole is substantially aligned with the resonator stack.

18. The method of claim 17, wherein etching the stress mitigation structure and the transducer substrate to form the substrate cavity comprises using the laminated stress mitigation material as an etch mask.

19. The method of claim 14, wherein the stress mitigation structure is attached to the package substrate using an adhesive.

20. A packaged micro-electromechanical systems (MEMS) transducer device, comprising:
a transducer substrate having a first coefficient of thermal expansion (CTE);
a membrane on the transducer substrate over a cavity formed through the transducer substrate;
a resonator stack on the membrane; and
a stress mitigation structure between the transducer substrate and a package substrate having a second CTE greater than the first CTE, wherein the stress mitigation structure has a third CTE less than both the first CTE and the second CTE, the stress mitigation structure counter-acting physical responses of the package substrate to temperature fluctuations to reduce stress induced onto the transducer substrate.
